(19) United States
(12) Patent Application Publication
(10) Pub. No.: US 2025/0054809 A1
(43) Pub. Date: Feb. 13, 2025

(54) FULLY SELF-ALIGNED VIA WITH GRAPHENE CAP

(71) Applicant: Tokyo Electron Limited, Tokyo (JP)

(72) Inventors: Kandabara Tapily, Albany, NY (US); Subhadeep Kal, Albany, NY (US); Peng Wang, Albany, NY (US); Peter Biolsi, Albany, NY (US)

(21) Appl. No.: 18/366,492

(22) Filed: Aug. 7, 2023

(51) Int. Cl. H01L 21/768; H01L 21/311

(52) U.S. Cl. CPC H01L 21/76802; H01L 21/31116; H01L 21/76829; H01L 21/7685; H01L 21/76879

(57) ABSTRACT

A method of processing a substrate that includes: forming a pattern of an electrically conductive layer over the substrate, the electrically conductive layer and a first dielectric layer being exposed at a surface of the substrate; selectively depositing a graphene layer over the electrically conductive layer relative to the first dielectric layer; selectively depositing a second dielectric layer over the first dielectric layer relative to the graphene layer; and depositing a third dielectric layer over the substrate, the third dielectric layer covering the second dielectric layer and the graphene layer.

### TECHNICAL FIELD

The present invention relates generally to methods of processing a substrate, and, in particular embodiments, to fully self-aligned via (FSAV) with graphene cap.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Process flows used to form the constituent structures of semiconductor devices often involve depositing and removing a variety of materials while a pattern of several materials may be exposed in a surface of the working substrate.

The minimum dimension of features in a patterned layer is shrunk periodically to roughly double the component density at each successive technology node, thereby reducing the cost per function. Innovations in patterning, such as immersion deep ultraviolet (i-DUV) lithography, multiple patterning, and 13.5 nm wavelength extreme ultraviolet (EUV) optical systems have brought some critical dimensions down close to ten nanometers. This squeezes the margin for pattern misalignment and puts pressure on process integration to provide self-aligned structures to prevent electrical opens and shorts in middle-of-line (MOL) and back-end-of-line (BEOL) interconnect elements. Innovative process flows for fabricating self-aligned structures may rely on availing highly selective etch and deposition processing techniques, thereby challenging semiconductor processing technology such as plasma enhanced deposition and etching to innovate and provide the requisite unit processes with the nanoscale precision, uniformity, and repeatability that IC manufacturing demands.

### SUMMARY

In accordance with an embodiment of the present invention, a method of processing a substrate that includes: forming a pattern of an electrically conductive layer over the substrate, the electrically conductive layer and a first dielectric layer being exposed at a surface of the substrate; selectively depositing a graphene layer over the electrically conductive layer relative to the first dielectric layer; selectively depositing a second dielectric layer over the first dielectric layer relative to the graphene layer; and depositing a third dielectric layer over the substrate, the third dielectric layer covering the second dielectric layer and the graphene layer.

In accordance with an embodiment of the present invention, a method of processing a substrate that includes: forming a first recess in a first dielectric layer of the substrate; filling the first recess with an electrically conductive material; selectively depositing a graphene layer over the electrically conductive material; selectively depositing a second dielectric layer over the first dielectric layer; depositing a third dielectric layer over the substrate to cover the graphene layer and the second dielectric layer; performing a first etch process to form a second recess in the third dielectric layer, the recess being aligned with a portion of the first recess; and performing a second etch process to extend the second recess and expose the graphene layer, the second etch process being selective to the graphene layer.

In accordance with an embodiment of the present invention, a method of processing a substrate, the method including: performing a dual-damascene process to form a recess, a carbon-containing material being exposed at a bottom of the recess; heating the substrate in vacuum or under an inert gas flow to thermally decompose and remove the carbon-containing material, and expose an electrically conductive layer; and forming a graphene layer over the electrically conductive layer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1G illustrate cross sectional views of an example substrate during an example process of semiconductor fabrication comprising fully self-aligned via (FSAV) formation at various stages in accordance with various embodiments, wherein FIG. 1A illustrates an incoming substrate comprising a first dielectric material and an electrically conductive material, FIG. 1B illustrates the substrate after selectively depositing a graphene layer, FIG. 1C illustrates the substrate after selectively depositing a second dielectric material (dielectric-on-dielectric deposition), FIG. 1D illustrates the substrate after depositing an interlayer dielectric (ILD) and forming a patterned hardmask layer, FIG. 1E illustrates the substrate after a first pattern transfer etch (i.e., via opening etch), FIG. 1F illustrates the substrate after a second pattern transfer etch (i.e., via landing etch), and FIG. 1G illustrates the substrate after metallization;

FIGS. 2A-2C illustrate cross sectional views of another example substrate during an example process of semiconductor fabrication comprising fully self-aligned via (FSAV) formation at various stages in accordance with other embodiments, wherein FIG. 2A illustrates an incoming substrate comprising a first ILD and a second ILD, FIG. 2B illustrates the substrate after a first pattern transfer etch (i.e., via opening etch), and FIG. 2C illustrates the substrate after a second pattern transfer etch (i.e., via landing etch);

FIG. 3 illustrates a cross sectional view of an example substrate at an intermediate stage during an example process of semiconductor fabrication comprising a conformal etch stop layer (ESL) formation and fully self-aligned via (FSAV) formation in accordance with an alternate embodiment;

FIG. 4 illustrates a cross sectional view of an example substrate at an intermediate stage during an example process of semiconductor fabrication comprising a selective etch stop layer (ESL) formation and fully self-aligned via (FSAV) formation in accordance with an another embodiment;

FIG. 5 illustrates a cross sectional view of an example substrate comprising a thick graphene layer at an intermediate stage during an example process of semiconductor fabrication fully self-aligned via (FSAV) formation in accordance with an alternate embodiment;

FIGS. 6A-6H illustrate cross sectional views of an example substrate during an example process of semiconductor fabrication comprising fully self-aligned via (FSAV) formation at various stages in accordance with yet other embodiments, wherein FIG. 6A illustrates an incoming substrate comprising an electrically conductive material, a first dielectric material, and a second dielectric material, FIG. 6B illustrates the substrate after depositing a sacrificial fill, FIG. 6C illustrates the substrate after an etch back, FIG. 6D illustrates the substrate after depositing an interlayer dielectric (ILD), FIG. 6E illustrates the substrate after forming a recess comprising a trench and a via, FIG. 6F illustrates the substrate after removing the sacrificial fill, FIG. 6G illustrates the substrate after selectively depositing a graphene layer, and FIG. 6H illustrates the substrate after metallization; and

FIGS. 7A-7C illustrate process flow charts of methods of graphene deposition for fully self-aligned via (FSAV) formation in accordance with various embodiments, wherein FIG. 7A illustrates an embodiment process flow, FIG. 7B illustrates an alternate embodiment process flow, and FIG. 7C illustrate another alternate embodiment process flow.

### DETAILED DESCRIPTION OF ILLUSTRATIVE EMBODIMENTS

This application relates to a method of processing a substrate, more particularly to fully self-aligned vias (FSAV) formation with a graphene cap. Techniques herein may include methods of patterning substrates such as for back end of line (BEOL) metallization process and dual damascene process. As device feature size continues to scale down, minimizing the device contact resistance has become a significant challenge especially for tight metal pitch. To mitigate the device contact resistance at joins of interconnects, a metallic capping layer may be used. Recently, 2D materials such as graphene have been shown to be able to minimize electromigration as well as to reduce the total line resistance. However, graphene and other 2D materials are generally sensitive to processing condition and prone to damage from conventional patterning integration. For example, graphene may be severely damaged by conventional plasma etching processes for FSAV formation (e.g., via opening and via landing), which prevents these materials from successfully applied as a capping layer for interconnects in BEOL processes.

Embodiments of the present application disclose methods of fully self-aligned vias (FSAV) formation with a graphene cap. The methods of FSAV formation in various embodiments may combine selective graphene deposition and selective dielectric on dielectric (DoD) deposition. The selective DoD deposition can form a dielectric support layer adjacent to the graphene cap. The dielectric support layer may improve the alignment and directionality of via formation. In certain embodiments, the dielectric support layer may advantageously replace an etch stop layer (ESL), which may be difficult to remove selectivity without damaging the graphene cap or compromising the via profile. Alternately, the dielectric support layer may be used with the ESL. Further, the methods of FSAV formation may use a sacrificial fill to temporarily cover a pattern of metal lines during the via formation. The sacrificial fill may be removed after the via is formed and a graphene cap may be selectively deposited.

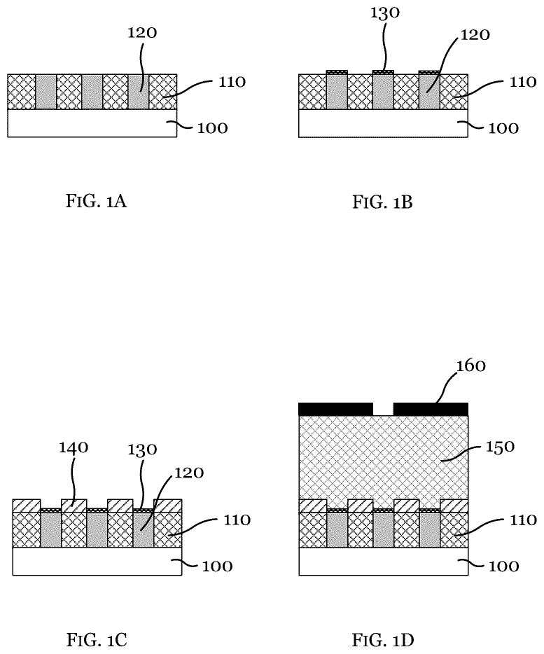

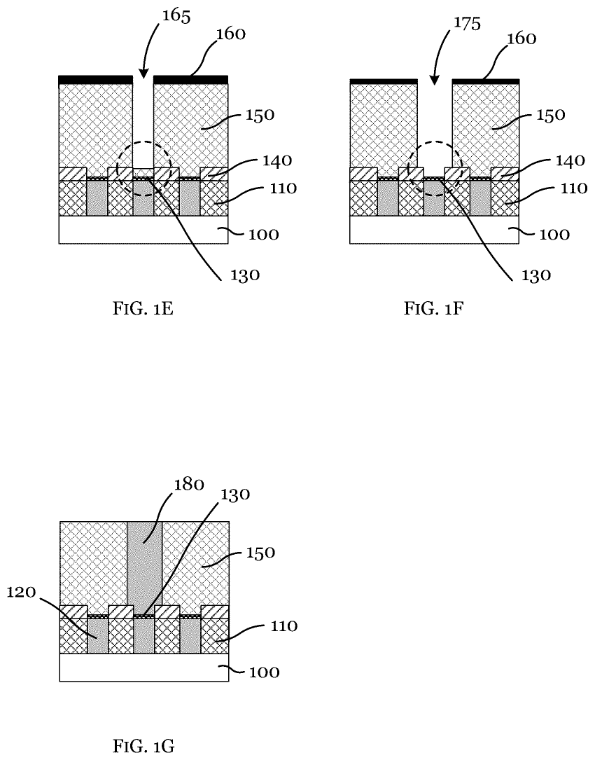

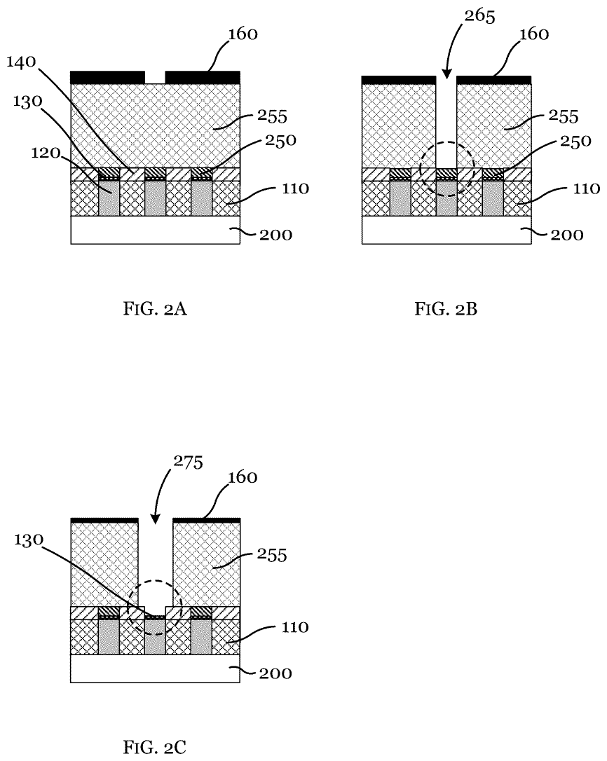

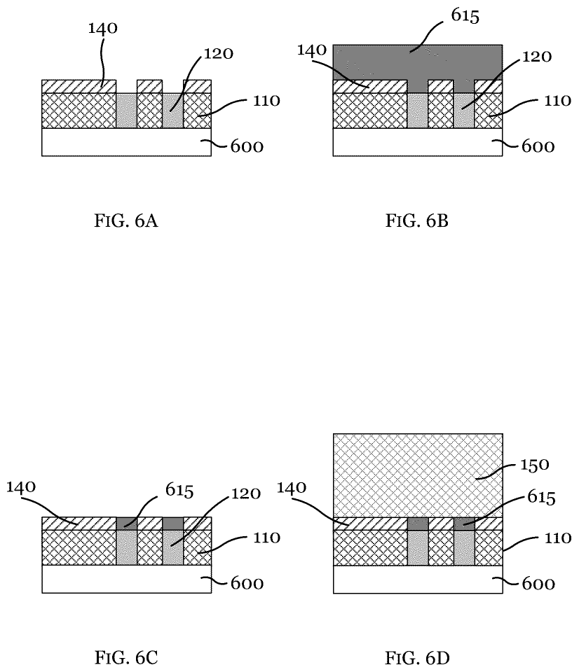

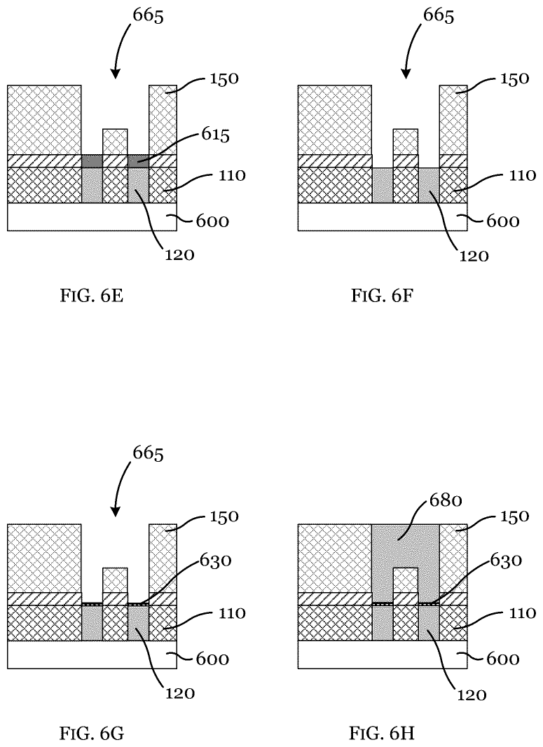

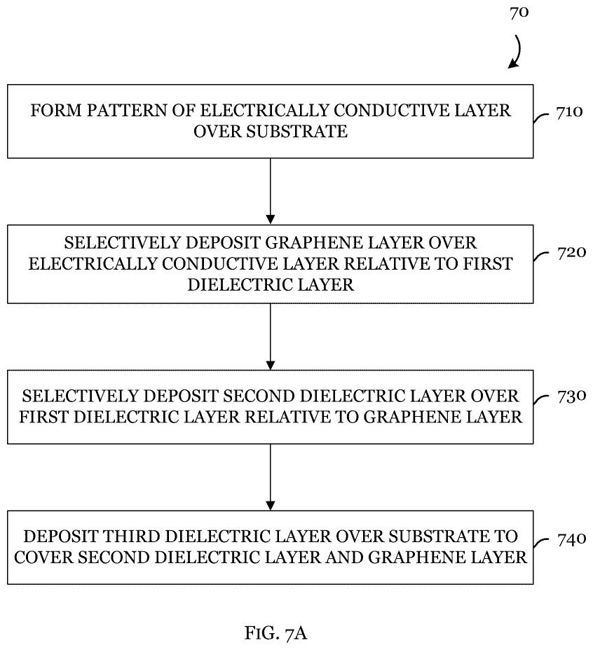

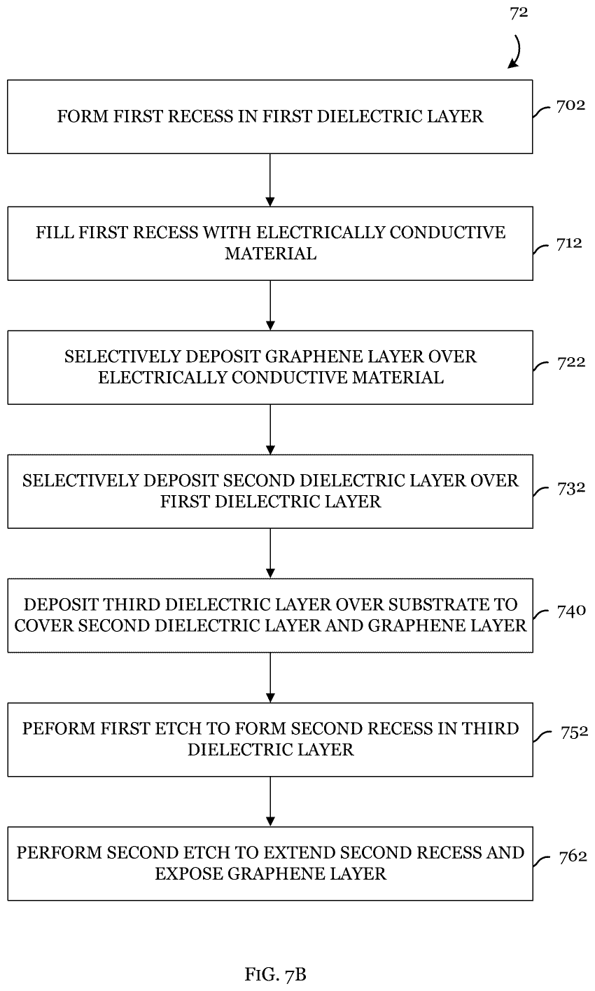

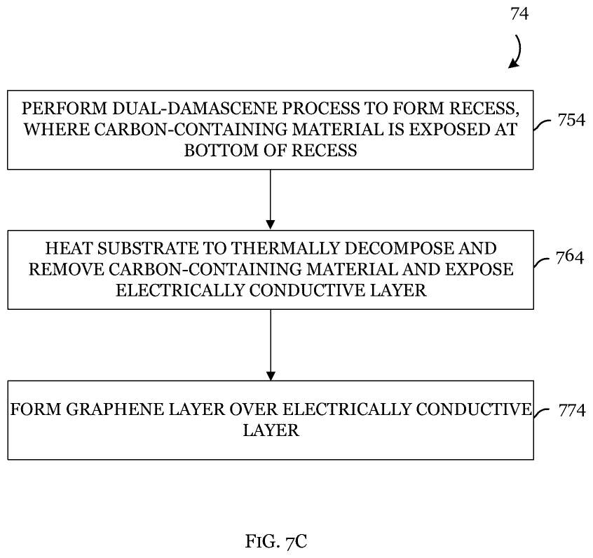

In the following, FIGS. 1A-1G illustrate steps of semiconductor fabrication including the FSAV formation with a graphene cap in accordance with various embodiments. Process steps and intermediate structures in accordance with alternate embodiments are described referring to FIGS. 2A-2C and 3-5. Embodiments with a sacrificial fill are then described referring to FIGS. 6A-6H. Several embodiment process flows of the graphene cap formation are described referring to FIGS. 7A-7C. All Figures in the disclosure, including the aspect ratios of features, are not to scale and for illustration purposes only. Although various embodiments of this disclosure describe the selective deposition of graphene and dielectric in the context of fully self-aligned vias (FSAV) formation, the methods of deposition may be applied to form any other recess features (e.g., line and trench) where a layer of graphene may be used. In this disclosure, any list that presents possible compositions, conditions, or process variations includes any reasonable combination thereof, and thus the term “or” used in the list does not indicate any exclusive selection of a particular composition, condition, or process variation.

FIGS. 1A-1G illustrate cross sectional views of an example substrate during an example process of semiconductor fabrication comprising fully self-aligned via (FSAV) formation at various stages in accordance with various embodiments.

FIG. 1A illustrates an incoming substrate 100 comprising a first dielectric material 110 and an electrically conductive material 120. In FIG. 1A, the substrate 100 may be a part of, or include, a semiconductor device, and may have undergone a number of steps of processing following, for example, a conventional process. The substrate 100 accordingly may comprise layers of semiconductors useful in various microelectronics. For example, the semiconductor structure may comprise the substrate 100 in which various device regions are formed. FIG. 1A illustrates only a simplified example of the substrate 100 and the methods of FSAV formation may be applied to any other reasonable structures.

In one or more embodiments, the substrate 100 may be a silicon wafer, or a silicon-on-insulator (SOI) wafer. In certain embodiments, the substrate 100 may comprise a silicon germanium wafer, silicon carbide wafer, gallium arsenide wafer, gallium nitride wafer and other compound semiconductors. In other embodiments, the substrate 100 comprises heterogeneous layers such as silicon germanium on silicon, gallium nitride on silicon, silicon carbon on silicon, as well layers of silicon on a silicon or SOI substrate. In various embodiments, the substrate 100 is patterned or embedded in other components of the semiconductor device.

As illustrated in FIG. 1A, the substrate 100 may further comprise patterns of the first dielectric material 110 and the electrically conductive material 120 (referred to as conductive material in this disclosure). In various embodiments, the structure illustrated in FIG. 1A may be formed by forming and patterning a layer of the first dielectric material 110 for recess formation, followed by filling the recess with the conductive material 120. In certain embodiments, although not specifically illustrated in FIG. 1A, a barrier/liner layer may be interposed between the first dielectric material 110 and the conductive material 120 to prevent diffusion and improve the isolation of the conductive material 120. In one or more embodiments, the conductive material 120 may not be in direct contact with the top surface of the substrate 100, and all of the bottom and sidewalls of the conductive material 120 may be surrounded by the first dielectric material 110 or the barrier/liner layer.

In various embodiments, the conductive material 120 may be a part of interconnects for the semiconductor device being fabricated. In certain embodiments, the conductive material 120 may comprise Cu, Al, Ta, Ti, W, Ru, Co, Ni, Mo, Nb, alloys or a combination thereof. In one or more embodiments, the conductive material 120 may comprise more than one metal. In various embodiments, the first dielectric material 110 may comprise silicon (Si). In certain embodiments, the first dielectric material 110 comprises silicon oxide or a low-k dielectric material. In one or more embodiments, the pattern of the conductive material 120 may have a pitch size of 30 nm or less.

In various embodiments, the substrate 100 may have been planarized with the top surfaces of the conductive material 120 and the first dielectric material 110 in the same horizontal plane. In certain embodiments, the planarization may utilize a chemical mechanical planarization (CMP) process, followed by a cleaning process to remove any impurities.

In certain embodiments, prior to performing selective graphene deposition (FIG. 1B), an optional pretreatment may be performed to remove any surface oxide so that the top surface of the conductive material 120 becomes accessible for subsequent process steps. In various embodiments, the optional pretreatment may be a wet process. In one example, an alcohol solution may be contacted with the substrate 100 at room temperature for a predetermined time. The alcohol solution may comprise one or more alcohols or, alternatively, the alcohol solution may comprise one or more alcohols and a non-oxidizing solvent. The alcohol solution can contain any alcohol with a chemical formula R—OH. One class of alcohols is primary alcohols, of which methanol and ethanol are the simplest members. Another class of alcohols is secondary alcohols, for example isopropyl alcohol (IPA). In certain embodiments, the optional pretreatment may also comprise a step to remove moisture from the substrate 100. The removal of moisture may be performed, for example, by a thermal treatment under an inert gas flow. In another embodiment, the optional pretreatment may comprise a dry process using one or more reducing gases with or without a plasma.

FIG. 1B illustrates a cross sectional view of the substrate 100 after selectively depositing a graphene layer.

As the first step of the FSAV formation process, the graphene may be selectively deposited over the conductive material 120 to form a graphene cap 130. The graphene deposition may occur selectively occur over the conductive material 120 only, and thus the first dielectric material 110 may remain uncovered. Although not wishing to be limited by any theory, a hydrophobic surface of the first dielectric material 110 can generally improve the selectivity of graphene deposition. Accordingly, in FIG. 1B, three graphene caps are illustrated for example, corresponding to three exposed surface regions of the conductive material 120. The selective graphene deposition may be performed using a suitable selective deposition process such as a chemical vapor deposition (CVD), plasma enhanced CVD (PECVD), atomic layer deposition (ALD), or plasma enhanced ALD (PEALD) process with an appropriate graphene precursor. In another embodiment, the selective graphene may be performed using a layer transfer method.

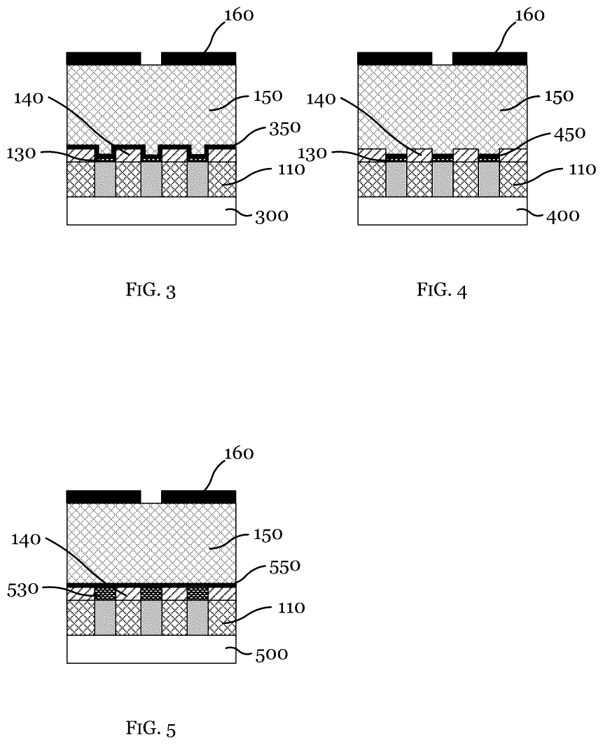

In various embodiments, the graphene cap 130 may comprise a single graphene sheet or several graphene sheets, and thus have a thickness of one to several atomic layers (e.g., <1 nm). The material properties of graphene such as superior electrical conductivity makes graphene an attractive alternative to form a capping layer compared to conventional metals. Further, the use of 2D materials can advantageously enable a very thin capping layer. In another embodiment, the graphene cap 130 may comprise more than several graphene sheets to form a thick graphene layer (e.g., 5-10 nm), as further described below (FIG. 5).

In one or more embodiments, prior to subsequent deposition steps, an optional post-graphene treatment such as annealing may be performed to remove any impurities and/or improve the quality of graphene deposited.

FIG. 1C illustrates a cross sectional view of the substrate 100 after selectively depositing a second dielectric material 140 (dielectric-on-dielectric deposition).

After the selective graphene deposition, a selective dielectric-on-dielectric (DoD) deposition may be performed. In various embodiments, as illustrated in FIG. 1C, the second dielectric material 140 is deposited selectively on the exposed first dielectric material 110, and not over the graphene cap 130. The second dielectric material 140 may function as a support dielectric layer in the subsequent process steps (e.g., FIGS. 1E-1F) to improve the alignment and directionality of the via formation. In various embodiments, the second dielectric material 140 has a thickness between 2 nm and 10 nm. In certain embodiments, the second dielectric material 140 may comprise SiCN, SiOCN, SiO₂. SiON, or a combination thereof. In other embodiments, the second dielectric material 140 may comprise Al₂O₃, AlN, BN, TiN, or TiO₂. In various embodiments, the selective DoD deposition may be performed using a vapor deposition technique such as chemical vapor deposition (CVD), physical vapor deposition (PVD), and atomic layer deposition (ALD), as well as other plasma processes such as plasma enhanced CVD (PECVD), sputtering, and other processes. In another embodiment, the DoD may be performed using a solution based inhibition.

According to one embodiment, the selective DoD deposition may comprise adsorbing a metal-containing catalyst layer on the first dielectric material 110, and in the absence of any oxidizing and hydrolyzing agent, at a substrate temperature of approximately 150° C., or less, exposing the substrate 100 to a process gas containing a silanol gas to deposit a SiO₂ film. For example, the silanol gas may be selected from the group consisting of tris(tert-pentoxy) silanol, tris(tert-butoxy) silanol, and bis(tert-butoxy) (isopropoxy) silanol. The metal-containing catalyst layer can, for example, include aluminum (Al) or titanium (Ti). In one example, the metal-containing catalyst layer may be formed by exposing the substrate to AlMe₃ gas. In one example, the silanol gas is selected from the group consisting of tris(tert-pentoxy) silanol, tris(tert-butoxy) silanol, and bis(tert-butoxy) (isopropoxy) silanol.

In various embodiments, subsequent process steps following the selective DoD deposition (e.g., FIG. 1C) may comprise additional layer formation and their patterning for fully self-aligned vias (FSAV) formation followed by metallization as a part of a back-end-of-line (BEOL) fabrication process. One exemplary process flow is further described below referring to FIGS. 1D-1G, but other process flows may also be possible. In one embodiment, an optional etch stop layer (ESL) may be formed to cover the surface of the graphene cap 130 and the second dielectric material 140. It will be appreciated that any suitable features might be formed, including (whether or not considered “recesses”) holes, trenches, and/or other suitable structures, using embodiments of this disclosure.

FIG. 1D illustrates a cross sectional view of the substrate 100 after depositing an interlayer dielectric (ILD) 150 and forming a patterned hardmask layer 160.

In FIG. 1D, the ILD 150 may be formed over the substrate 100 and covers the surface of the graphene cap 130 and the second dielectric material 140. In various embodiments, ILD 150 comprises a third dielectric material and may be deposited by flowable-CVD, followed by planarization. Over the ILD 150, as illustrated in FIG. 1D, the patterned hardmask layer 160 may be formed. The patterned hardmask layer 160 may define a relief pattern to be transferred into the ILD 150 for forming vias. The ILD 150 may comprise silicon oxide or a suitable low-k dielectric material.

In certain embodiments, although not specifically illustrated in FIG. 1D, in addition to the ILD 150, a layer stack useful for the FSAV formation may be formed over the substrate 100. For example, the layer stack may comprise an etch stop layer (ESL), an additional patterned hardmask layer, and a planarizing layer. In various embodiments, one or more conventional photolithographic processes may be used to pattern layers of the hardmask. In one embodiment, the additional patterned hardmask layer may define another relief pattern to be transferred into the ILD 150 for forming line recesses or trenches, and may be disposed below the patterned hardmask layer 160 such that the patterning of the ILD 150 can form both a line recess and vias for a dual-damascene process.

FIG. 1E illustrates a cross sectional view of the substrate 100 after a first pattern transfer etch (i.e., via opening etch).

The pattern of the patterned hardmask layer 160 may be first transferred into the ILD 150 by the first pattern transfer etch (via opening etch). For the first pattern transfer etch, anisotropic etch techniques such as a reactive ion etch (RIE) may be used. Because the plasma conditions for the first pattern transfer etch to etch the ILD 150 efficiently with directionality may easily damage the underlying structure, the first pattern transfer etch may need to be terminated before etching through the entire thickness of the ILD 150. Accordingly, after the first pattern transfer etch, as illustrated in FIG. 1E, a recess 165 formed in the ILD 150 may not reach to the bottom of the ILD 150 or expose the top surface of the graphene cap 130. In certain embodiments, it may be preferable that the recess 165 is deep enough to reach the second dielectric material 140 but not reaching to the graphene cap 130 as indicated by a dotted circle in FIG. 1E.

In certain embodiments, the first pattern transfer etch may be timed such that the etch may be terminated before the recess 165 reaches the bottom of the ILD 150. In one or more embodiments, after the first pattern transfer etch, a portion of the sidewalls of the second dielectric material 140 may be exposed. The height difference of the second dielectric material 140 and the graphene cap 130 may advantageously be used to determine the desired end point for the first pattern transfer etch. For example, in one embodiment, etch products may be monitored real-time by appropriate chemical analysis tools (e.g., optical emission spectroscopy), where the detection of chemical elements from the second dielectric material 140 indicates that the recess 165 reaches to the level of the second dielectric material 140 and the process is approaching the top surface of the graphene cap 130.

FIG. 1F illustrates a cross sectional view of the substrate 100 after a second pattern transfer etch (i.e., via landing etch).

After the first pattern transfer etch (via opening etch), the second pattern transfer etch (i.e., via landing etch) may be performed to extend the recess 165 in FIG. 1E into an extended recess 175, where the graphene cap 130 may be exposed at the bottom of the extended recess 175 as illustrated in FIG. 1F. For the second pattern transfer etch, etch techniques such as a reactive ion etch (RIE) may be used. In various embodiments, the second pattern transfer etch may be a plasma etch process or a chemical vapor etch (non-plasma) process. In certain embodiments, the second pattern transfer etch may also use the patterned hardmask layer 160 used for the first pattern transfer etch as an etch mask. The remaining portion of the ILD 150 at the bottom of the recess 165 may be removed as indicated by a dotted circle in FIG. 1F. The second pattern transfer etch may be anisotropic or isotropic, and in various embodiments, it may be performed selectively to graphene so that little to no damage may be made to the graphene cap 130.

In certain embodiments, the directionality of the second pattern transfer etch (anisotropy), the etch rate, or both may be compromised to realize the desired etch selectivity for the second pattern transfer etch. As a result, as illustrated in FIG. 1F, the extended recess 175 may have a critical dimension (CD) slightly wider than the recess 165 in FIG. 1E. In general, the CD widening during the FSAV formation needs to be controlled and minimized because it can lead to the misalignment of via and interconnects. Advantageously, the second dielectric material 140 can function as a support dielectric layer that mitigates the adverse effect of the CD widening. For example, the material for the second dielectric material 140 may be selected such that it may not be etched during the second pattern transfer etch. Consequently, the CD widening may be limited to the sidewalls of the ILD 150 and not happening at the bottom of the extended recess 175 (the dotted circle in FIG. 1F).

Another benefit of the support dielectric layer is the ability to eliminate an etch stop layer (ESL) for the graphene cap 130 in certain embodiments as illustrated in FIG. 1F. In conventional methods, the ESL may be deposited over the graphene cap 130. However, the ESL may typically be deposited to form a uniform layer to cover the entire surface and thus need to be removed after patterning the ILD 150 to expose the graphene cap 130. The inventors of this application identified that the removal of the ESL can be challenging because it may damage graphene and/or a lateral etch of the ESL can result in CD widening at the bottom of the recess. This issue may be overcome by replacing the ESL with a pattern of the support dielectric layer that is selectively formed over the first dielectric material 110 and not over the graphene cap 130, which eliminates the need of removal to expose the graphene cap 130.

In certain embodiments, the first and second pattern transfer etches may be performed in a same processing chamber, and the first pattern transfer etch may be switched to the second pattern transfer etch by adjusting plasma process parameters (e.g., process gas composition, gas flow rates, pressure, temperature, source power, bias power, and pulsing scheme). Alternately, the two etches may be performed in different processing chambers of a cluster tool, where the substrate may be transported from one chamber to the other without exposure to ambient environment.

After the second pattern transfer etch, any remainder of the patterned hardmask layer 160 and other intermediate layers that might have been used may be removed using a suitable wet or dry etch process or a combination of several etch process steps.

FIG. 1G illustrates a cross sectional view of the substrate 100 after metallization.

In various embodiments, the extended recess 175 may be filled with a conductive fill 180 comprising an electrically conductive material by a metallization process. In various embodiments, the conductive fill 180 may comprise Cu, Al, Ta, Ti, W, Ru, Co, Ni, Mo, Nb, alloys or a combination thereof. In certain embodiments, the conductive fill 180 may be the same as the conductive material 120. In one or more embodiments, the metallization may be performed by a seed layer deposition of a metal (e.g., copper) using a sputtering or physical vapor deposition (PVD) technique followed by electroplating. Additionally, a planarization may be performed using a chemical mechanical planarization (CMP) method to remove an excess of the conductive fill 180 on surface.

In certain embodiments, the conductive fill 180 may comprise a layer stack comprising an adhesion liner and/or diffusion barrier layer in addition to the primary fill material of the electrically conductive material. For example, the liner materials and diffusion barriers may comprise Ti, TiN, Ta, TaN, Ru, Co, 2D materials such as transition metal dichalcogenides (TMDs) or a combination thereof.

FIGS. 2A-2C illustrate cross sectional views of another example substrate 200 during an example process of semiconductor fabrication comprising fully self-aligned via (FSAV) formation at various stages in accordance with other embodiments.

In prior embodiments illustrated in FIGS. 1A-1G, a single layer of interlayer dielectric (ILD) was used. In other embodiments, more than one ILD may be used to further improve the process of FSAV formation with graphene cap. In particular, the layer stack structure for ILD, combined with the support dielectric layer, may improve the timing of switching the two pattern transfer etches. The steps of selective graphene deposition and selective dielectric-on-dielectric (DoD) deposition may be identical to the prior embodiments described above referring to FIGS. 1A-1C, and thus only subsequent steps starting a step of ILD deposition will be described below.

FIG. 2A illustrates a cross sectional view of an incoming substrate 200 comprising a first ILD 250 and a second ILD 255.

In FIG. 2A, the substrate 200 comprising patterns of a first dielectric material 110 and an electrically conductive material 120. Further, the patterns of the substrate 200 may be selectively covered by a graphene cap 130 and a second dielectric material 140, similar to those illustrated in FIG. 1C. In various embodiments, the two ILDs (the first ILD 250 and the second ILD 255) may be sequentially deposited over the substrate 200 by flowable-CVD, followed by planarization. As illustrated in FIG. 2A, the first ILD 250 may fill the gaps between the second dielectric materials 140 over the graphene cap 130 such that the top surfaces of the first ILD 250 and the second dielectric material 140 are substantially flat, followed by depositing the second ILD 255 over the flat surface. In other embodiments, the top surface of the first ILD 250 may be lower or higher than the top surface of the second dielectric material 140.

In various embodiments, the material for the first ILD 250 may be selected to be more etch resistant during the first pattern transfer etch (via opening etch) than the second ILD 255, which can advantageously slow the etch rate of the first pattern transfer etch when the process approaches to the endpoint. This may particularly be helpful in providing a sufficient time window for determining when to switch the first etch process to the second. In one embodiment, the first ILD 250 and the second ILD 255 may comprise silicon oxide, but the density of silicon oxide for the first ILD 250 may be selected to be higher to realize a sufficient etch rate difference between the two ILDs. In another embodiment, the first ILD 250 and the second ILD 255 may comprise different low-k dielectric materials. A patterned hardmask layer 160 may be formed over the second ILD 255 and may define a relief pattern to be transferred into the ILDs for forming vias. Similar to prior embodiments, although not specifically illustrated in FIG. 2A, in addition to the two ILDs, a layer stack useful for the FSAV formation may be formed over the substrate 200 (e.g., an ESL, an additional patterned hardmask layer, and a planarizing layer).

FIG. 2B illustrates a cross sectional view of the substrate 200 after a first pattern transfer etch (i.e., via opening etch).

The pattern of the patterned hardmask layer 160 may be first transferred into the second ILD 255 by the first pattern transfer etch (via opening etch), which may follow the same process as described above referring to FIG. 1E. In various embodiments, a recess 265 may be formed in the second ILD 255 and may not reach to the top surface of the graphene cap 130 as indicated by a dotted circle in FIG. 2B. In certain embodiments, a portion of the first ILD 250 may also be etched, but the first pattern transfer etch may be terminated before exposing the graphene cap 130.

FIG. 2C illustrates a cross sectional view of the substrate 200 after a second pattern transfer etch (i.e., via landing etch).

After the first pattern transfer etch (via opening etch), the second pattern transfer etch (i.e., via landing etch) may be performed to extend the recess 265 in FIG. 2B into an extended recess 275, where the graphene cap 130 may be exposed at the bottom of the extended recess 275 as illustrated in FIG. 2C. The first ILD 250 at the bottom of the recess 265 in FIG. 2B may be removed as indicated by a dotted circle in FIG. 2C. The second pattern transfer etch may be anisotropic or isotropic, and in various embodiments, it may be performed selectively to graphene so that little to no damage may be made to the graphene cap 130.

In certain embodiments, an etch stop layer (ESL) may be used in addition to the dielectric support layer to further protect the graphene cap. Embodiments with the ESL are described below referring to FIGS. 3-5. The incoming substrate structures as well as the steps of selective graphene deposition and selective dielectric-on-dielectric (DoD) deposition may be identical to the prior embodiments described above referring to FIGS. 1A-1C, and thus will not be repeated. Further, the substrates illustrated in FIGS. 3-5 may be processed in the same way as prior embodiments by two pattern transfer etches (e.g., FIGS. 1E-1F) and metallization (e.g., FIG. 1G), which will not be repeated.

FIG. 3 illustrates a cross sectional view of an example substrate 300 at an intermediate stage during an example process of semiconductor fabrication comprising a conformal etch stop layer (ESL) formation and fully self-aligned via (FSAV) formation in accordance with an alternate embodiment.

In FIG. 3, a conformal ESL 350 may be deposited after the selective DoD deposition to cover the surface of a graphene cap 130 and a second dielectric material 140 over the substrate 300. An interlayer dielectric (ILD) 150 and a patterned hardmask layer 160 may then be formed over the conformal ESL 350. In various embodiments, the conformal ESL 350 may comprise silicon carbide, silicon nitride, other silicon-based materials, aluminum oxide, aluminum nitride, or zirconium oxide. The conformal ESL 350 may have a different composition from the second dielectric material 140. The conformal ESL 350 may be deposited using deposition techniques such as vapor deposition including chemical vapor deposition (CVD), physical vapor deposition (PVD), and atomic layer deposition (ALD), as well as other plasma processes such as plasma enhanced CVD (PECVD), sputtering, and other processes. In certain embodiments, the thickness of the conformal ESL 350 may be between 2 nm to 5 nm.

The substrate 300 in FIG. 3 may be then processed by the first pattern transfer etch (e.g., FIG. 1E) to form a recess, which may advantageously stopped by the conformal ESL 350 without risking an excess etch to expose the graphene cap 130 below the conformal ESL 350. A removal step for the conformal ESL 350 may follow the first pattern transfer etch. The removal of the conformal ESL 350 may be performed as a separate etch step prior to the second pattern transfer etch or integrated into the second pattern transfer etch. Advantageously, the dielectric support layer of the second dielectric material 140 can minimize the lateral etch during the ESL removal and the second pattern transfer etch. In one embodiment, the conformal ESL 350 may comprise silicon nitride, and the ESL removal may be based on a thermal removal process.

FIG. 4 illustrates a cross sectional view of an example substrate 400 at an intermediate stage during an example process of semiconductor fabrication comprising a selective etch stop layer (ESL) formation and fully self-aligned via (FSAV) formation in accordance with an another embodiment.

In FIG. 4, a selective ESL 450 may be deposited after the selective DoD deposition to cover the surface of a graphene cap 130 selectively over the substrate 400. Area selective deposition (ASD) techniques may be used such that a second dielectric material 140 may be free from the selective ESL 450. In various embodiments, the selective ESL 450 may comprise a same or similar material as the conformal ESL 350. An interlayer dielectric (ILD) 150 and a patterned hardmask layer 160 may then be formed over the substrate 400. In certain embodiments, the thickness of the selective ESL 450 may be between 2 nm to 5 nm. In one or more embodiments, the top surface of the selective ESL 450 may be lower than that of the second dielectric material 140.

FIG. 5 illustrates a cross sectional view of an example substrate 500 comprising a thick graphene layer at an intermediate stage during an example process of semiconductor fabrication fully self-aligned via (FSAV) formation in accordance with an alternate embodiment.

In FIG. 5, the selective graphene deposition (e.g., FIG. 1B) may be performed to enable a thick graphene layer 530 comprising a larger number of graphene sheets, where the layer may be thicker than several graphene sheets. In one embodiment, the thick graphene layer 530 may have a thickness between 2 nm and 10 nm. Such a thick graphene layer may potentially be used as a parallel conductor in semiconductor devices. In FIG. 5, the height of the thick graphene layer 530 and that of a second dielectric material 140 are drawn to be substantially the same in accordance with one embodiment. In other embodiments, however, there may be a height different and the surface may comprise steps between these materials. After the selective graphene deposition, a selective DoD deposition (e.g., FIG. 1C), an ESL formation to deposit a conformal ESL 550, and an ILD deposition (e.g., FIG. 1D) may be performed.

In yet other embodiments, most of FSAV formation steps may be performed first prior to selective graphene deposition. To protect the underlying conductive lines, a sacrificial fill may be used in these embodiments as a part of dual-damascene process.

FIGS. 6A-6H illustrate cross sectional views of an example substrate 600 during an example process of semiconductor fabrication comprising fully self-aligned via (FSAV) formation at various stages in accordance with yet other embodiments. The incoming substrate structures as well as some process steps of deposition and etching may be identical to the prior embodiments described above, and thus will not be repeated. Although the process flow in FIGS. 6A-6H describes a part of a dual-damascene process flow, the methods may be applied to a single-damascene process flow or other patterning processes.

FIG. 6A illustrates a cross sectional view of an incoming substrate 600 comprising an electrically conductive material 120 (referred to as conductive material 120), a first dielectric material 110, and a second dielectric material 140.

Unlike prior embodiments where the selective graphene deposition precedes the selective DoD deposition, the second dielectric material 140 may be deposited first to selectively cover the first dielectric material 110. As an example, FIG. 6A illustrates a cross section of the two conductive lines made of the conductive material 120 to be connected.

FIG. 6B illustrates a cross sectional view of the substrate 600 after depositing a sacrificial fill 615.

In various embodiments, the sacrificial fill 615 may be deposited over the substrate 600 to cover the entire exposed surface. The sacrificial fill 615 may comprise a thermal decomposition material. In certain embodiments, the sacrificial fill 615 may comprise a carbon-containing material. In one embodiment, the thermal decomposition material may be comprised of an ashing-less carbon (ALC) material such as urea binding resin, specifically polyurea, which has characteristics that it can be removed by thermal treatment of less than 400° C. The removal of ALC material can advantageously be achieved in vacuum or under an inert gas flow, not requiring any plasma or ashing processes. The techniques for forming the polyurea include, but are not limited to, copolymerizing isocyanate and amine as raw material monomers to form a urea bond, for example, using a vapor deposition polymerization process. A liquid process may also be used to form the polyurea. It will be recognized, however, that other formation processes and other removal processes may be utilized. Further, it will be recognized that the techniques described herein are not limited to polyurea and other materials and/or combinations or variants of polyurea and other materials may be utilized as the thermal decomposition material. In an alternate embodiment, the thermal decomposition material may be comprised of polypyrrole, i.e., a polymer derived from pyrrole (C₄H₄NH) as a monomer. In yet another embodiment, the sacrificial fill 615 may comprise an oxide.

In certain embodiments, a vapor deposition polymerization process to form the ALC material may be performed at a temperature between 40° C. to 150° C., or in one embodiment between 70° C. to 100° C. In various embodiments, the process temperature for the vapor deposition polymerization process may be selected based on the types of raw material monomers and/or their respective vapor pressures. For example, when the vapor pressures of the raw material monomers are relatively low, the process temperature may be relatively high, whereas when the vapor pressures of the raw material monomers are relatively high, the process temperature may be relatively low.

FIG. 6C illustrates a cross sectional view of the substrate 600 after an etch back or planarization.

Any excess of the sacrificial fill 615 may be removed by an etch back process or planarization to expose the second dielectric material 140 as illustrated in FIG. 6C. As a result, the sacrificial fill 615 may only cover the conductive material 120.

FIG. 6D illustrates a cross sectional view of the substrate 600 after depositing an interlayer dielectric (ILD) 150.

In FIG. 6D, the ILD 150 may be formed over the substrate 600 and covers the surface of the sacrificial fill 615 and the second dielectric material 140. In various embodiments, ILD 150 comprises a third dielectric material and may be deposited by flowable-CVD, followed by planarization. The ILD 150 may comprise silicon oxide or a suitable low-k dielectric material.

FIG. 6E illustrates a cross sectional view of the substrate 600 after forming a recess comprising a trench and a via.

In various embodiments, a recess 665 comprising a trench and a via may be formed in the ILD 150. As an example, the recess 665 in FIG. 6E has two vias reaching to the sacrificial fill 615 and a trench that connects the two vias. To form the recess 665, a series of etching processes such as a reactive ion etch (RIE) may be performed using one or more patterned masks (not illustrated).

FIG. 6F illustrates a cross sectional view of the substrate 600 after removing the sacrificial fill 615.

One advantage of using a thermal decomposition material for the sacrificial fill 615 is the ability to remove the sacrificial fill 615 from the substrate only by heating. Applying sufficient heat, the thermal decomposition material may decompose and escape into vapor from the substrate 600. This removal process therefore may be performed without requiring a harsh etch treatment (e.g., the use of aggressive etchant or a plasma process) that may cause damage to other portions of the substrate (e.g., the ILD 150 and the conductive material 120). In various embodiments, the removal of the sacrificial fill 615 may be performed by heating the substrate 600 to a temperature below 400° C., for example between 200° C. to 350° C. in vacuum or under a flow of inert gas. After the removal, the conductive material 120 may be exposed at the bottom of the vias of the recess 665.

FIG. 6G illustrates a cross sectional view of the substrate 600 after selectively depositing a graphene cap 630.

In various embodiments, after the via formation as described above (FIGS. 6A-6F), the graphene may be selectively deposited over the conductive material 120 to form a graphene cap 630. The selective graphene deposition may be performed using a suitable selective deposition process such as a chemical vapor deposition (CVD), plasma enhanced CVD (PECVD), atomic layer deposition (ALD), or plasma enhanced ALD (PEALD) process with an appropriate graphene precursor.

FIG. 6H illustrates a cross sectional view of the substrate 600 after metallization.

In various embodiments, the recess 665 may be filled with a conductive fill 680 comprising an electrically conductive material by a metallization process. In various embodiments, the conductive fill 680 may comprise Cu, Al, Ta, Ti, W, Ru, Co, Ni, Nb, or Mo. Additionally, a planarization may be performed using a chemical mechanical planarization (CMP) method to remove an excess of the conductive fill 680 on surface. In certain embodiments, the conductive fill 680 may comprise a layer stack comprising an adhesion liner and/or diffusion barrier layer in addition to the primary fill material of the electrically conductive material.

FIGS. 7A-7C illustrate process flow charts of methods of graphene deposition for fully self-aligned via (FSAV) formation in accordance with various embodiments. The process flows can be followed with the figures (FIGS. 1A-1F and 6E-6G) discussed above and hence will not be described again.

In FIG. 7A, a process flow 70 starts with forming a pattern of an electrically conductive layer over the substrate, where the electrically conductive layer and a first dielectric layer are exposed at a surface of the substrate (block 710, FIG. 1A). Next, a graphene layer may be selectively deposited over the electrically conductive layer relative to the first dielectric layer (block 720, FIG. 1B), followed by selectively depositing a second dielectric layer over the first dielectric layer relative to the graphene layer (block 730, FIG. 1C). A third dielectric layer may then be deposited over the substrate to cover the second dielectric layer and the graphene layer (block 740, FIG. 1D).

In FIG. 7B, another process flow 72 starts with forming a first recess in a first dielectric layer of the substrate (block 702), followed by filling the first recess with an electrically conductive material (block 712, FIG. 1A). Subsequently, a graphene layer may be selectively deposited over the electrically conductive material (block 722, FIG. 1B), and a second dielectric layer may be selectively deposited over the first dielectric layer (block 732, FIG. 1C). A third dielectric layer may then be deposited over the substrate to cover the second dielectric layer and the graphene layer (block 740, FIG. 1D). Next, a first etch process may be performed to form a second recess in the third dielectric layer, where the recess is aligned with a portion of the first recess (block 752, FIG. 1E). After the first etch process, a second etch process may be performed to extend the second recess and expose the graphene layer, where the second etch process is selective to the graphene layer (block 762, FIG. 1F).

In FIG. 7C, yet another process flow 74 starts with performing a dual-damascene process to form a recess, where a carbon-containing material is exposed at a bottom of the recess (block 754, FIG. 6E). Next, the substrate may be heated in vacuum or under an inert gas flow to thermally decompose and remove the carbon-containing material and expose an electrically conductive layer (block 764, FIG. 6F), followed by forming a graphene layer over the electrically conductive layer (block 774, FIG. 6G).

Example embodiments of the invention are described below. Other embodiments can also be understood from the entirety of the specification as well as the claims filed herein.

Example 1. A method of processing a substrate that includes: forming a pattern of an electrically conductive layer over the substrate, the electrically conductive layer and a first dielectric layer being exposed at a surface of the substrate; selectively depositing a graphene layer over the electrically conductive layer relative to the first dielectric layer; selectively depositing a second dielectric layer over the first dielectric layer relative to the graphene layer; and depositing a third dielectric layer over the substrate, the third dielectric layer covering the second dielectric layer and the graphene layer.

Example 2. The method of example 1, further including: patterning the third dielectric layer to form a recess, the third dielectric layer covering the graphene layer after the patterning, the recess being aligned with a portion of the pattern of the electrically conductive layer; and extending the recess to expose the graphene layer.

Example 3. The method of one of examples 1 or 2, where the patterning includes an anisotropic plasma etch using a first plasma, and where the extending includes an isotropic etch that is selective to the graphene layer.

Example 4. The method of one of examples 1 to 3, further including: monitoring etch products generated from the patterning; and terminating the patterning when an element of the second dielectric layer is detected in the etch products.

Example 5. The method of one of examples 1 to 4, further including, depositing a fourth dielectric layer over the third dielectric layer.

Example 6. The method of one of examples 1 to 5, further including: patterning the fourth dielectric layer to form a recess, the third dielectric layer being exposed at a bottom of the recess after the patterning; and patterning the third dielectric layer to extend the recess and expose the graphene layer.

Example 7. The method of one of examples 1 to 6, further including: prior to depositing the third dielectric layer, depositing an etch stop layer (ESL) over the substrate; patterning the third dielectric layer to form a recess, the ESL being exposed at a bottom of the recess after the patterning; and removing the ESL to expose the graphene layer.

Example 8. The method of one of examples 1 to 7, where the first dielectric layer and the third dielectric layer include silicon oxide, and where the second dielectric layer includes silicon cabonitride, silicon oxycarbonitirde, silicon oxide, titanium oxide, titanium nitride, aluminum oxide, aluminum nitride, or boron nitride.

Example 9. A method of processing a substrate that includes: forming a first recess in a first dielectric layer of the substrate; filling the first recess with an electrically conductive material; selectively depositing a graphene layer over the electrically conductive material; selectively depositing a second dielectric layer over the first dielectric layer; depositing a third dielectric layer over the substrate to cover the graphene layer and the second dielectric layer; performing a first etch process to form a second recess in the third dielectric layer, the recess being aligned with a portion of the first recess; and performing a second etch process to extend the second recess and expose the graphene layer, the second etch process being selective to the graphene layer.

Example 10. The method of example 9, where a top surface of the second dielectric layer is positioned higher than a top surface of the graphene layer.

Example 11. The method of one of examples 9 or 10, where the recess is formed as a fully self-aligned via, the method further including, after the second etch process, filling the extended second recess with a second electrically conductive material.

Example 12. The method of one of examples 9 to 11, where the second dielectric layer has a thickness between 2 nm and 10 nm.

Example 13. The method of one of examples 9 to 12, where a top surface of the second dielectric layer is positioned at a same level as a top surface of the graphene layer, the method further including, prior to depositing the third dielectric layer, depositing an etch stop layer (ESL) over the substrate, and where the ESL is exposed at a bottom of the second recess after the first etch process, and where the second etch process removes the ESL.

Example 14. The method of one of examples 9 to 13, where the ESL includes SiN, SiCN, SiOCN, or SiON.

Example 15. A method of processing a substrate that includes: performing a dual-damascene process to form a recess, a carbon-containing material being exposed at a bottom of the recess; heating the substrate in vacuum or under an inert gas flow to thermally decompose and remove the carbon-containing material, and expose an electrically conductive layer; and forming a graphene layer over the electrically conductive layer.

Example 16. The method of example 15, further including: prior to the dual-damascene process, forming a pattern of the electrically conductive layer over the substrate, the electrically conductive layer and a first dielectric layer being exposed at a surface of the substrate; selectively depositing a second dielectric layer over the first dielectric layer relative to the electrically conductive layer; depositing the carbon-containing material to cover the electrically conductive layer and the second dielectric layer; performing an etch back process to expose the second dielectric layer and form a flat surface including the second dielectric layer and the carbon-containing material; and depositing a third dielectric layer over the flat surface, where the dual-damascene process patterning the third dielectric layer.

Example 17. The method of one of examples 15 or 16, where the recess is aligned with a portion of the pattern of the electrically conductive layer.

Example 18. The method of one of examples 15 to 17, where the deposition of the carbon-containing material is performed using a vapor deposition process at a temperature between 40° C. to 150° C.

Example 19. The method of one of examples 15 to 18, where the carbon-containing material has a decomposition temperature range between 200° C. to 350° C.

Example 20. The method of one of examples 15 to 19, further including, after forming the graphene layer, filling the recess with a second electrically conductive material, the second electrically conductive material being in physical contact with the graphene layer.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
forming a pattern of an electrically conductive layer over the substrate, the electrically conductive layer and a first dielectric layer being exposed at a surface of the substrate;
selectively depositing a graphene layer over the electrically conductive layer relative to the first dielectric layer;
selectively depositing a second dielectric layer over the first dielectric layer relative to the graphene layer; and
depositing a third dielectric layer over the substrate, the third dielectric layer covering the second dielectric layer and the graphene layer.

2. The method of claim 1, further comprising:
patterning the third dielectric layer to form a recess, the third dielectric layer covering the graphene layer after the patterning, the recess being aligned with a portion of the pattern of the electrically conductive layer; and
extending the recess to expose the graphene layer.

3. The method of claim 2, wherein the patterning comprises an anisotropic plasma etch using a first plasma, and wherein the extending comprises an isotropic etch that is selective to the graphene layer.

4. The method of claim 2, further comprising:
monitoring etch products generated from the patterning; and
terminating the patterning when an element of the second dielectric layer is detected in the etch products.

5. The method of claim 1, further comprising, depositing a fourth dielectric layer over the third dielectric layer.

6. The method of claim 5, further comprising:
patterning the fourth dielectric layer to form a recess, the third dielectric layer being exposed at a bottom of the recess after the patterning; and
patterning the third dielectric layer to extend the recess and expose the graphene layer.

7. The method of claim 1, further comprising:
prior to depositing the third dielectric layer, depositing an etch stop layer (ESL) over the substrate;
patterning the third dielectric layer to form a recess, the ESL being exposed at a bottom of the recess after the patterning; and
removing the ESL to expose the graphene layer.

8. The method of claim 1, wherein the first dielectric layer and the third dielectric layer comprise silicon oxide, and wherein the second dielectric layer comprises silicon carbonitride, silicon oxycarbonitride, silicon oxide, titanium oxide, titanium nitride, aluminum oxide, aluminum nitride, or boron nitride.

9. A method of processing a substrate, the method comprising:
forming a first recess in a first dielectric layer of the substrate;
filling the first recess with an electrically conductive material;
selectively depositing a graphene layer over the electrically conductive material;
selectively depositing a second dielectric layer over the first dielectric layer;
depositing a third dielectric layer over the substrate to cover the graphene layer and the second dielectric layer;
performing a first etch process to form a second recess in the third dielectric layer, the recess being aligned with a portion of the first recess; and
performing a second etch process to extend the second recess and expose the graphene layer, the second etch process being selective to the graphene layer.

10. The method of claim 9, wherein a top surface of the second dielectric layer is positioned higher than a top surface of the graphene layer.

11. The method of claim 9, wherein the recess is formed as a fully self-aligned via, the method further comprising, after the second etch process, filling the extended second recess with a second electrically conductive material.

12. The method of claim 9, wherein the second dielectric layer has a thickness between 2 nm and 10 nm.

13. The method of claim 9, wherein a top surface of the second dielectric layer is positioned at a same level as a top surface of the graphene layer, the method further comprising, prior to depositing the third dielectric layer, depositing an etch stop layer (ESL) over the substrate, and wherein the ESL is exposed at a bottom of the second recess after the first etch process, and wherein the second etch process removes the ESL.

14. The method of claim 13, wherein the ESL comprises SiN, SiCN, SiOCN, or SiON.

15. A method of processing a substrate, the method comprising:
performing a dual-damascene process to form a recess, a carbon-containing material being exposed at a bottom of the recess;
heating the substrate in vacuum or under an inert gas flow to thermally decompose and remove the carbon-containing material, and expose an electrically conductive layer; and
forming a graphene layer over the electrically conductive layer.

16. The method of claim 15, further comprising:
prior to the dual-damascene process, forming a pattern of the electrically conductive layer over the substrate, the electrically conductive layer and a first dielectric layer being exposed at a surface of the substrate;
selectively depositing a second dielectric layer over the first dielectric layer relative to the electrically conductive layer;
depositing the carbon-containing material to cover the electrically conductive layer and the second dielectric layer;
performing an etch back process to expose the second dielectric layer and form a flat surface comprising the second dielectric layer and the carbon-containing material; and
depositing a third dielectric layer over the flat surface, wherein the dual-damascene process includes patterning the third dielectric layer.

17. The method of claim 16, wherein the recess is aligned with a portion of the pattern of the electrically conductive layer.

18. The method of claim 16, wherein the deposition of the carbon-containing material is performed using a vapor deposition process at a temperature between 40° C. to 150° C.

19. The method of claim 15, wherein the carbon-containing material has a decomposition temperature range between 200° C. to 350° C.

20. The method of claim 15, further comprising, after forming the graphene layer, filling the recess with a second electrically conductive material, the second electrically conductive material being in physical contact with the graphene layer.
